(19) United States
(12) Patent Application Publication
(10) Pub. No.: US 2013/0120020 A1
(43) Pub. Date: May 16, 2013

(54) ADAPTIVE OUTPUT SWING DRIVER

(71) Applicants: Miao Li, San Diego, CA (US); Behnam Amelifard, San Diego, CA (US); Xiaohua Kong, San Diego, CA (US); Nam V. Dang, San Diego, CA (US)

(72) Inventors: Miao Li, San Diego, CA (US); Behnam Amelifard, San Diego, CA (US); Xiaohua Kong, San Diego, CA (US); Nam V. Dang, San Diego, CA (US)

(73) Assignee: QUALCOMM INCORPORATED, San Diego, CA (US)

(21) Appl. No.: 13/294,482

(22) Filed: Nov. 11, 2011

(51) Int. Cl. H03K 19/003

(52) U.S. Cl. 326/30

(57) ABSTRACT

An adjustable gain line driver receives an input signal and a gain control signal and outputs a signal with a swing, and the swing is measured to generate a swing measurement signal. A target swing signal is generated having a target swing, and the target swing signal is measured to generate a target swing reference signal. The swing measurement signal is compared to the target swing reference control signal and a counter generating the gain control signal is incremented until the measurement signal meets the target swing reference signal. Optionally a reset signal resets the counter, and the gain control signal, at predetermined events.

### FIELD OF DISCLOSURE

The present Application for Patent relates to line drivers, more particularly, to active impedance matched transmission cable drivers.

### BACKGROUND

Cables such as High Definition Multi-Media Interface (HDMI) are often used to carry data signals from a source unit to a destination unit among, for example, any of a set top box, home theatre center or other multimedia device. To ensure that the data signals from the source unit, when received by a destination unit at an opposite end of the cable are within signal quality specifications, “transmission line buffers” or “line drivers,” collectively referenced hereinafter as “line drivers,” drive the cable with the data signals from the source unit end. The line drivers provide impedance matching with the cable and, to an extent, compensation for impedance mismatches at the load end of the cable.

To provide interchangeability among different cables having different impedances, and among different destination units having different input impedances, the line driver can be configured with a selectable or switchable output impedance, i.e., can be configured to provide selectable impedance matching. However, this can present issues regarding the output swing of the line driver, namely that if the output swing is set with respect to one impedance, substituting with a different impedance may change that output swing. Conventional feedback-type automatic gain control within the line drivers can be provided, but there are various costs. For example, the source unit may be supplied with a voltage, such as 1.8V, that is lower than the line driver output swing, for example 3V, which can render conventional feedback-type gain control impractical.

### SUMMARY

The following summary is not an extensive overview of all contemplated aspects, and is not intended to identify key or critical elements of all aspects nor delineate the scope of any aspect. Its sole purpose is to present some concepts of one or more aspects in a simplified form as a prelude to the more detailed description that is presented later.

Various exemplary embodiments provide a method for adjusting an output swing of a driver that can include generating a target swing measurement signal, generating a swing measurement signal based on a magnitude of the output swing, controlling the output swing based on the swing measurement signal and the target swing measurement signal. In an aspect, controlling the output swing can include controlling a plurality of line drivers based on the swing control signal

In one aspect, generating the swing measurement signal can include extracting an AC component of the output swing, and generating the swing measurement signal based on the extracted AC component. In one further aspect, generating the swing measurement signal based on the extracted AC component can include rectifying the AC component to generate a DC swing measurement signal, generating the swing measurement signal based on the DC measurement signal.

In another aspect relating, for example, to the various exemplary embodiments providing a method for adjusting an output swing of a driver, controlling the output swing can include comparing the swing measurement signal to the target swing measurement signal and adjusting the output swing based, at least in part, on the comparing.

In still another aspect, adjusting the output swing based, at least in part, on the comparing can include incrementing a counter output count in response to the comparing indicating the swing measurement signal to be lower than the target swing measurement signal, increasing the output swing based on the counter output count. One related aspect can include repeating the comparing the swing measurement signal to the target swing measurement signal and adjusting the output swing based, at least in part, on the comparing until the comparing indicates the swing measurement signal to be not lower than the target swing measurement signal.

In another aspect relating, for example, to the various exemplary embodiments providing a method for adjusting an output swing of a driver, an adjusting can include resetting a swing control signal to a start value, controlling the output swing based on the swing control signal, generating an updated swing measurement signal based on the magnitude of the output swing, increasing the swing control signal and, further, can include repeating the controlling the output swing, generating the updated swing measurement signal and increasing the swing control signal until the updated swing measurement signal is not less than a given target swing measurement.

In a related aspect, the swing control signal can be a counter output, and resetting the swing control signal can reset the counter output, and increasing the swing control signal can comprise incrementing the counter output.

In another aspect relating, for example, to the various exemplary embodiments providing a method for adjusting an output swing of a driver, generating the target swing measurement signal can include generating a high swing voltage and a low swing voltage based on a reference voltage, and can further include generating the target swing measurement signal based, at least in part, on the high swing voltage and the low swing voltage. In one related aspect, generating the target swing measurement signal can further include generating a common mode reference voltage, midpoint between the high swing voltage and the low swing voltage, and wherein the AC component is extracted as a swing relative to the common mode reference voltage.

In another aspect relating, for example, to the various exemplary embodiments providing a method for adjusting an output swing of a driver, the can driver include a selectable output impedance selectable from a plurality of impedances, and example methods according to this aspect can further include selecting an output impedance from the plurality of impedances, resetting a swing control signal to a start value, controlling the output swing based on the swing control signal, generating an updated swing measurement signal based on the magnitude of the output swing, increasing the swing control signal, and can further include repeating the controlling the output swing, generating the updated swing measurement signal and increasing the swing control signal until the updated swing measurement signal is not less than a given target swing measurement.

Various exemplary embodiments can provide a driver swing adjustment apparatus for a driver having a signal input, a signal output, and a swing control input, and examples can comprise a swing measurement circuit coupled to the signal output, for generating a swing measurement signal according to a swing on the signal output, a target swing measurement signal generator for generating a target swing measurement signal according to a target swing reference voltage, and a feedback signal generator for providing a control signal to the swing control input, based on the swing measurement signal and the target swing measurement signal.

In one aspect, an example driver swing adjustment apparatus according to various exemplary embodiments can include a comparator that compares the swing measurement signal to the target swing measurement signal and generates a corresponding comparison result, and can include a swing increase circuit that generates the control signal based on the comparison result.

In one aspect, a driver swing adjustment apparatus according to various exemplary embodiments can include a counter to receive a system clock and to increment a counter output based on the system clock and the comparison result, and that outputs the control signal based on the counter output. In a further aspect, the counter can have a reset input and can reset the counter output in response to given reset signal on the reset input. In a still further aspect, the comparator can generate the comparison result as a swing increase enable signal when the swing measurement signal is less than the target swing measurement signal, and as a swing increase not enable signal when the swing measurement signal is not less than the target swing measurement signal, and wherein the counter increments the counter output in response to the swing increase enable signal and the system clock. In a still further aspect, the counter can have a reset input and can reset the counter output in response to a given reset signal on the reset input.

In one aspect, a driver swing adjustment apparatus according to various exemplary embodiments can include a target swing signal generator that, based on a given reference voltage, generates the target reference swing signal, wherein the target swing measurement circuit is AC coupled to the target reference swing signal. Further to this aspect, the target swing generator can generate a reference midpoint voltage and generate a low swing reference voltage. Still further to this aspect the target swing signal generator can generate a high swing reference voltage relative to the reference midpoint voltage, and generate the target reference swing signal based on the low swing reference voltage and the high swing reference voltage. Still further to this aspect, the target swing measurement circuit can extract an AC component of the target reference swing signal, and generate the target swing measurement signal based on the AC component relative to the reference midpoint voltage.

In one aspect, the swing measurement circuit can include a first full wave rectifier that rectifies the AC component to generate an unfiltered swing measurement signal and a first low pass smoothing filter that smoothes the unfiltered swing measurement signal and outputs the swing measurement signal as a corresponding DC swing signal.

In another aspect, the target swing measurement circuit comprises a second full wave rectifier that rectifies the high swing reference voltage and the low swing reference voltage to generate an unfiltered target swing measurement signal and a second low pass smoothing filter that smoothes the unfiltered target swing measurement signal and outputs the target swing measurement signal as a corresponding DC target swing signal.

Various exemplary embodiments can provide an adjustable swing cable driver apparatus for a driver having a signal input, differential signal outputs, and a swing control input and, further to the exemplary embodiments, can include a selectable output impedance matching bridge coupling the differential signal outputs, a swing measurement circuit coupled to the differential signal outputs, for generating a swing measurement signal according to a swing on the signal output, a target swing signal generator for generating a target swing measurement signal according to a target reference swing and, still further can include a feedback signal generator for providing a control signal to the swing control input, based on the swing measurement signal and the target swing measurement signal.

Various exemplary embodiments can provide methods for adjusting an output swing of a driver, and such methods can include step of generating a target swing measurement signal, step of generating a swing measurement signal based on a magnitude of the output swing, and step controlling the output swing based on the swing measurement signal and the target swing measurement signal.

In one aspect, methods according to such embodiments can include a step of repeating the step of comparing the swing measurement signal to the target swing measurement signal and the step of adjusting the output swing based, at least in part, on the step of comparing, until the comparing indicates the swing measurement signal to be not lower than the target swing measurement signal.

In one aspect of methods for adjusting an output swing of a driver according to one exemplary embodiment, the driver can include a selectable output impedance selectable from a plurality of impedances, and methods according to this aspect can further include step of selecting an output impedance from the plurality of impedances, step of resetting a swing control signal to a start value, step of controlling the output swing based on the swing control signal, step of generating an updated swing measurement signal based on the magnitude of the output swing, step of increasing the swing control signal; and repeating, in order, the step of controlling the output swing, the step of generating the updated swing measurement signal and the step of increasing the swing control signal until the updated swing measurement is not less than a given target swing measurement.

Various exemplary embodiments can provide an apparatus for adjusting an output swing of a driver, and such apparatus can include means for generating a target swing measurement signal, means for generating a swing measurement signal based on a magnitude of the output swing, and means for controlling the output swing based on the swing measurement signal and the target swing measurement signal.

According to one aspect of various exemplary embodiments providing an apparatus for adjusting an output swing of a driver, the apparatus can further include means for repeating the comparing the swing measurement signal to the target swing measurement signal and adjusting the output swing based, at least in part, on the comparing until the comparing indicates the swing measurement signal to be not lower than the target swing measurement signal.

According to one aspect of various exemplary embodiments providing an apparatus for adjusting an output swing of a driver, the apparatus can further include: means for resetting a swing control signal to a start value, means for controlling the output swing based on the swing control signal, means for generating an updated swing measurement signal based on the magnitude of the output swing; means for increasing the swing control signal, and means for repeating the controlling the output swing, generating the updated swing measurement signal and increasing the swing control signal until the updated swing measurement is not less than a given target swing measurement.

According to one aspect of various exemplary embodiments providing an apparatus for adjusting an output swing of a driver, the apparatus can further include, or apply to, a selectable output impedance selectable from a plurality of impedances, and the apparatus can further include means for selecting an output impedance from the plurality of impedances, means for resetting a swing control signal to a start value, means for controlling the output swing based on the swing control signal, means for generating an updated swing measurement signal based on the magnitude of the output swing, means for increasing the swing control signal, and means for repeating the controlling the output swing, generating the updated swing measurement signal and increasing the swing control signal until the updated swing measurement is not less than a given target swing measurement.

In one further aspect of various exemplary embodiments providing an apparatus for adjusting an output swing of a driver, the apparatus can further include means for controlling the output swing of a plurality of line drivers based on the swing control signal.

### BRIEF DESCRIPTION OF THE DRAWINGS

FIG. 1 shows a simplified schematic diagram of one example line driver automatic swing adjustment circuit according to one exemplary embodiment.

FIG. 2 shows a simplified schematic diagram of one example line driver automatic swing adjustment circuit, with rectifier based AC to DC converting units, according to one exemplary embodiment.

FIG. 3 shows a simplified schematic diagram of one example automatic multi-line cable automatic swing adjustment system according to one exemplary embodiment.

FIG. 4 shows a logical flow diagram of one example line driver automatic swing adjustment process according to one exemplary embodiment.

FIG. 5 shows a computer simulation result of certain characteristics of one example line driver automatic swing adjustment circuit according to various embodiments, in an aspect of swing adjustment according to one exemplary embodiment.

### DETAILED DESCRIPTION

The detailed description set forth below in connection with the appended drawings is intended as a description of exemplary embodiments and is not intended to represent the only embodiments in which the present invention can be practiced. The word “exemplary” (and variants thereof) as used herein means serving as an example, instance, or illustration. Any aspect or design described herein as “exemplary” is not necessarily to be construed as preferred or advantageous over other aspects or designs. Rather, use of the word “exemplary” is only intended to illustrate example applications of concepts using simplified concrete examples.

Various specific details are also described, to facilitate a person of ordinary skill in the art in readily obtaining, through this disclosure in its entirety, a sufficient understanding of relevant concepts to practice according to one or more of the various exemplary embodiments. Such persons, though, upon reading this entire disclosure may see that various embodiments and aspects of one or more embodiments may be practiced without, or with alternatives to one or more of these specific details. In other instances, certain well-known structures and devices are shown in block diagram form to avoid obscuring the various novel ties of the exemplary embodiments.

Various aspects or features will be presented in terms of systems that may include a number of devices, components, modules, and the like. It is to be understood and appreciated that various systems may include additional devices, components, modules, and so forth, and/or may not include all devices, components, modules, and so on, discussed in connection with the figures. A combination of these approaches may also be used.

The terms “engine”, “component”, “module”, “system” and the like, as used herein, are intended to refer to a functional entity, which may be embodied in hardware, firmware, a combination of hardware and software, software, or software in execution. A “component” may be, but is not limited to being, a process running on a processor, a processor, an object, an executable, a thread of execution, a program, and/or a computer. By way of illustration, both an application running on a computing device and the computing device can be a component.

The term “includes,” as used in either the detailed description or the claims, is intended to be inclusive in a manner similar to the term “comprising” as “comprising” is interpreted when employed as a transitional word in a claim. The term “or,” as used in either the detailed description or the claims, is intended to mean an inclusive “or” rather than an exclusive “or.” In addition, the articles “a” and “an” as used in this disclosure should generally be construed to mean “one or more” unless specified otherwise or clear from the context to be directed to a singular form.

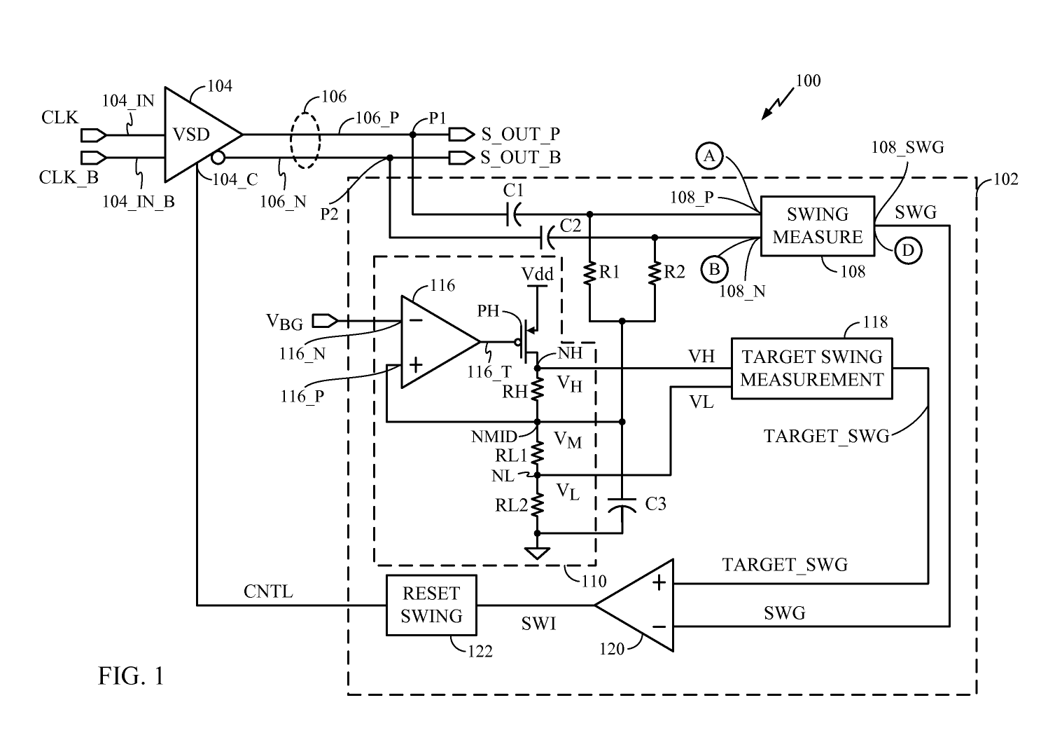

FIG. 1 shows a simplified block diagram of one example driver output swing automatic adjustment (alternatively referenced as “OSAA”) engine 102 according to at least one exemplary embodiment, in an example automatic adjusted swing (alternately referenced as “ADS”) cable drive system 100. The FIG. 1 ADS cable drive system 100 shows the example OSAA engine 102 according to at least one exemplary embodiment, in one example application of controlling via a control value (hereinafter “CNLT”) a given variable swing line driver (VSD) 104 coupled to a differential transmission line 106.

As a preliminary matter, regarding terminology, it will be understood that “output swing automatic adjustment”, its alternative “OSAA,” as well as “automatic adjusted swing” and its alternative “ADS,” are arbitrarily selected names, used only for consistency in identifying examples in this description, and have no inherently limiting meaning. It will be understood that the phrase “line driver” in the context of “variable swing line driver” is intended to encompass any circuit or device capable of receiving a signal and driving a cable or other transmission line based on the received signal and an output swing control, including but not limited, to any of a “line driver”, “buffer amplifier”, “line buffer”, and “impedance matching buffer,” and it will be understood that the selection of the name “line driver” among such alternative names is arbitrary, having no inherently limiting meaning. With respect to the structure and technology of the VSD 104, as will be understood by persons of ordinary skill in the art from this disclosure, provided that the VSD 104 is configured with a swing control input 104_C compatible with the selected format and range of the CNTL value, the VSD 104 is not necessarily particular to the embodiments, and can be selected and/or designed and constructed by such persons using, for example, conventional line driver selection and/or design techniques, based on conventional line driver considerations, such as load requirements, frequency band, available voltages, and cost constraints. Further detailed description is therefore omitted.

Referring to FIG.1, the ADS cable drive system 100 includes the VSD 104 identified above, having a differential driver input formed by 104_IN and 104_IN_B, receiving an input signal that, for this example, is a differential binary clock signal CLK and CLK_B (hereinafter collectively referenced as “CLK_IN”). The VSD 104 has a swing control input 104_C receiving a swing control signal (CNTL) that is generated by the OSAA engine 102 according to various exemplary embodiments, as described in greater detail at later sections. The VSD 104, in response to receiving a CLK_IN (or any other input signal) and a CNTL signal (or data) drives a Signal_OUT (not separately labeled on FIG. 1) onto the differential transmission line 106, with Signal_OUT consisting of one of a VOUT_{LOW} (not shown in FIG. 1) and VOUT_{HIGH} (not shown in FIG. 1) on the “positive” transmission line 106_P and its complement, the other of VOUT_{LOW} and VOUT_{HIGH} on the “negative” transmission line 106_N. The difference between VOUT_{HIGH} and VOUT_{LOW} is referenced hereinafter as the “swing” of Signal_OUT. The magnitude of the swing of Signal_OUT is determined by the CNTL value, the characteristics (e.g., drive capability) of the VSD 104, the load on the differential transmission line 106, and the selected output impedance (not explicitly shown in FIG. 1) of the VSD 104. It will be understood that the relational terms “complementary,” “positive,” and “negative” are not necessarily defined in a polarity sense. For example, a logical “1” or clock “ON” can be output by the VSD 104 as a VOUT_{HIGH} on the positive transmission line 106_P and a complement VOUT_{LOW} on the negative transmission line 106_N, with both VOUT_{LOW} and VOUT_{HIGH} being positive voltages between a given ground GND and a Vdd power rail.

Referring to FIG. 1, the OSAA engine 102 includes a swing measurement block 108 configured to generate from an output 108_SWG a signal SWG, preferably a sufficiently smooth DC signal, indicating the magnitude of the swing of the Signal_OUT appearing at points P1 and P2. Example implementations of the swing measurement block 108 are described in greater detail at later sections. Also, guidelines for determining “sufficiently smooth,” will be understood by persons of ordinary skill in the art from description of the functions and operations of SWG that are presented in greater detail at later sections. The OSAA engine 102 can include a target swing generator block 110 that, based on a given bandgap reference voltage V_{BG}, generates voltages V_{H} and V_{L} having a difference corresponding to the difference between the voltages of pulses caused by Signal_OUT at point P1 and P2 when the swing of Signal_OUT is at the target level. The OSAA engine 102 can also include a target swing measurement block 118 that generates a signal Target_SWG, preferably a sufficiently smooth DC signal, corresponding to the difference between V_{H} and V_{L}. In an aspect the target swing measurement block 118 can be configured identically (within fabrication tolerances) to the swing measurement block 108. Therefore, further to this aspect, Target-SWG functions as a target for the SWG.

Referring still to FIG. 1, in an aspect the OSAA engine 102 can include a swing comparator 120 configured to compare SWG and Target_SWG and generate a corresponding swing increase enable signal (SWI) that, for example, is received by a swing increase block 122. In an aspect the swing comparator 120 is configured to generate SWI at a value referenced as “swing increase enable” if SWG is less than Target_SWG and to otherwise generate SWI at a value referenced as a “swing increase not enable” value. The swing increase block 122, in response to SWI being at the swing increase enable level, increases CNTL by, for example, a predetermined increment. The swing increase block, in an aspect, does not increment when SWI is at the “swing increase not enable” value. As will be understood by persons of ordinary skill in the art from this disclosure, the specific values of a “swing increase enable” and “swing increase not enable” can depend on the particular structure selected for the swing increase block 122. In an example according to one aspect, the swing increase block 122 can be implemented as a counter, with CNTL being the count value, and SWI feeding a count enable (not specifically shown in FIG. 1). Further to this aspect, the SWI values of swing increase enable and swing increase not enable may be determined by the circuitry (not shown) of such a count enable.

Referring still to FIG. 1, in an aspect the swing increase block 122 can be configured to reset CNTL to a starting value in response to a RESET SWING signal, for example associated with a given reset event, such as a power up. In a related aspect, as will be described in greater detail at later sections, a selectable output impedance circuit (not shown in FIG. 1) can bridge across the complementary outputs of the VSD 104. The selectable output impedance circuit may be selectable, either continuously or discretely, to provide output impedance ranging from a given low to a given high. As understood by persons of ordinary skill in the art, if all other parameters (including the CNTL value) are held constant, and assuming there is a matching load impedance (not shown in FIG. 1), selecting a lower output impedance initially reduces the swing of Signal_OUT, while selecting a higher output impedance initially increases the swing. Therefore, to assure the initial swing of the VSD 104 is lower than the target swing after selecting any output impedance, the starting value of CNTL can be selected so that the resulting swing of the Signal_OUT will be lower than the target swing when the highest output impedance is selected.

Referring to FIG. 1, a resetting and swing adjustment according to at least one exemplary embodiment can be as follows: The above-described RESET SWING signal is applied to the FIG. 1 swing increase block 122, thereby re-setting CNTL to the starting value. The VSD 104 in response to the reset CNTL resets the swing to a starting value. As also described above, the starting CNTL is such that SWG output from the swing measurement block 108 will be less than Target_SWG output from the target swing measurement block 118. The SWI output from the swing comparator 120 is therefore at the increase swing enable value. The swing increase block 122 therefore increases, e.g., increments CNTL to increase the swing of the VSD 104. The swing measurement block 108 then generates an updated SWG which is again compared to Target_SWG by the swing comparator 120. This process can repeat the above-described loop, each loop causing the swing increase block 122 to increment CNTL, until SWG is no longer less than Target_SWG.

Referring to FIG. 1, one example coupling of the differential transmission line 106 to the OSAA engine 102, and generator of SWG by the swing measurement block 108 will be described. In one aspect the swing measurement block 108 of the OSAA engine 102 has a “positive” input 108_P coupled, preferably AC coupled, for example by a first swing measurement coupling capacitor Cl, to the positive transmission line 106_P, and has a “negative” input 108_N likewise coupled, for example by a second swing measurement coupling capacitor C2, to the negative transmission line 106_N. In an aspect a first termination resistor R1 couples the positive input terminal 108_P to a midpoint node NMID and a second termination resistor R2 couples the negative input terminal 108_N to the midpoint node NMID. In a related aspect, a termination capacitor C3 couples the midpoint node NMID to ground. In an aspect R1 is equal to R2 and the resistance value of both R1 and R2 can be selected to be significantly higher than an output impedance (not shown in FIG. 1) bridging the positive input 108_P and the negative input 108_N. As will be appreciated, the swing measurement block 108, in an aspect, through the swing measurement coupling capacitors C1 and C2, and the coupling of the midpoint node NMID coupling R1 and R2 to the midpoint node and midpoint voltage generated by the target swing generator block 110 as described in greater detail below, extracts an AC component from the Signal_OUT, from which it generates SWG.

Referring to FIG. 1, further to one aspect the values of R1, R2, Cl, C2 and C3 are selected such that a binary Signal_OUT forms a series of pulses (not shown in FIG. 1) at point VP coupled to the positive input 108_P of the swing measurement block 108, with a corresponding, complementary series of pulses (not shown in FIG. 1) at point VN coupled to the negative input 108_N of the swing measurement block 108. As will be appreciated by persons of ordinary skill in the art from this disclosure, the levels of the pulses will correspond to the difference between V_{HIGH} and V_{LOW}, i.e., to the Signal_OUT swing. In a related aspect the swing measurement block 108 can be configured, as described in greater detail at later sections, to convert the series of pulses on its positive and negative inputs 108_P, 108_N to a corresponding swing measurement signal SWG. In further related aspect, the swing measurement block 108 can be configured to output the swing measurement signal SWG as a smoothed DC value having a level corresponding to the Signal_OUT swing.

Referring still to FIG. 1, as will be understood by persons of ordinary skill in the art having view of this disclosure, in an example according to one or more exemplary embodiments, the swing measurement coupling capacitors C1 and C2 function as AC as a capacitive coupling, permitting an AC signal while blocking any DC signal. A new DC is re-generated as V_{M}, described in greater detail below, is coupled to the above-described AC signal, via the two termination resistors R1 and R2. Therefore, at the positive input 108_P and negative input 108_N, differential signals are re-generated, with the common-mode voltage V_{M}. The capacitor C3 helps to reduce the noise on V_{M}. Assuming, for example, a binary sequence of “101010” being placed on the positive and negative transmission lines 106_P and 106_N, respectively. The above-described capacitive coupling provided by swing measurement coupling capacitors C1 and C2 generates, in accordance with an aspect of one or more exemplary embodiments, a pulse sequence, corresponding to “101010” at the positive input 108_P and negative input 108_N. As will be appreciated by persons of ordinary skill in the art from reading this disclosure, this capacitive coupling, combined with other features of the OSAA engine 102 that are described in greater detail at later sections, provides detection of the output swing of Signal_OUT, and comparison of the detected output swing to a locally generated target swing signal Target_SWG, even though the maximum of Signal_OUT is higher than Vdd powering the OSAA engine 102. As will be understood by persons of ordinary skill in the art upon viewing this disclosure, Signal_OUT can exceed Vdd powering the OSAA engine 102 when the VSD 104 is powered by a voltage (not specifically shown in FIG. 1) higher than Vdd powering the OSAA engine 102.

Continuing to refer to FIG. 1, one example structure, and example operations of the example structure for the target swing generating block 110 will be described. In overview, one example target swing generating block 110 can include a difference amplifier 116 having an output 116_T coupled to a gate (shown but not separately numbered) of a current control PMOS transistor PM that feeds a current through a voltage ladder formed of, for example, three resistors, such as resistor RH, RL1 and RL2. The voltage ladder can have a midpoint node NMID coupled to a “+” input 116_P of the difference amplifier 116, with the “−” input 116_N of the difference amplifier 116 receiving a band gap voltage V_{BG}. The difference amplifier 116 thereby controls a current (not explicitly shown) from the power rail Vdd through the voltage ladder so that the voltage V_{M} at NMID is equal to the band gap voltage V_{BG}. In an aspect, the NMID is also coupled to the midpoint coupling of the termination resistors R1 and R2, which is also coupled to ground through the capacitor C3. The values of RH, RL1 and RL2 are selected such that a voltage V_{H} appears on the top node NH of the voltage ladder and a voltage V_{L} appears on a lower node NL of the voltage ladder, with the difference between V_{H} and V_{L} causing the target swing measurement block 118 to output Target_SWG at a value corresponding to the value of SWG when the swing of Signal_OUT is at the target level. Further regarding the values of RH, RL1 and RL2, setting RH equal to RL1 will place V_{M} in the middle between V_{H} and V_{L} (i.e., V_{H}−V_{M}=V_{M}−V_{L}). As previously described, the difference between V_{H} and V_{L} can be selected to be equal to the target swing, even though Signal_OUT swings at voltages higher than Vdd powering the OSAA engine 102.

Referring still to FIG. 1, to illustrate the above-described aspect, it will be assumed that the target swing of Signal_OUT if 500 mV and the voltage powering the VSD 104 is such that, at this target swing, Signal_OUT swings from about 2.8V to 3.3V. Therefore, referring to FIG. 1, in this example the pulses at the positive input 108_P and negative input 108_N can toggle around 1.2V, with a swing of 500 mV. It will also be assumed that Vdd powering the OSAA engine 102 is 1.8V, which is less than Signal_OUT. V_{M} (and therefore V_{BG}) can therefore be chosen to be approximately 1.2V and, for a 500 mV swing using this V_{M} as the center point V_{H} and V_{L} will be approximately 1.45V and 0.95V, respectively.

To generate Target_SWG as a sufficiently smooth, accurate DC signal for proper comparison with SWG at the swing comparator 120, the target swing measurement block 118 can, according to one aspect, be constructed and configured substantially identical to the swing measurement block 108. Also, as will be appreciated, constructing and configuring the target swing measurement block 118 substantially identical to the swing measurement block 108, can provide benefits of, for example, accuracy from unit to unit, and longer unit life may be obtained.

As previously described, in an aspect of the OSAA engine 102 according to at least one exemplary embodiment, the swing increase block 122 can be configured to generate CNTL as a multi-bit binary value, for example a counter value. In one aspect, such a multi-bit binary CNTL may be converted within the swing increase block 122 into an analog signal and communicated as such to the VSD 104. In another aspect such a multi-bit binary CNTL may be communicated in bit form, either parallel or serial, to the VSD 104. Further to this aspect, the VSD 104 can be configured with a digital to analog (D/A) converter (not shown in FIG. 1), or equivalent, to convert such a multi-bit binary CNTL to a signal format compatible with internal swing-adjusting circuitry (not shown) of the VSD 104. Such a D/A converter, and associated swing control circuitry of the VSD 104 can be in accordance with conventional digital gain control amplifier design, readily implemented by persons of ordinary skill in the art in view of this disclosure and, therefore, further detailed description is omitted.

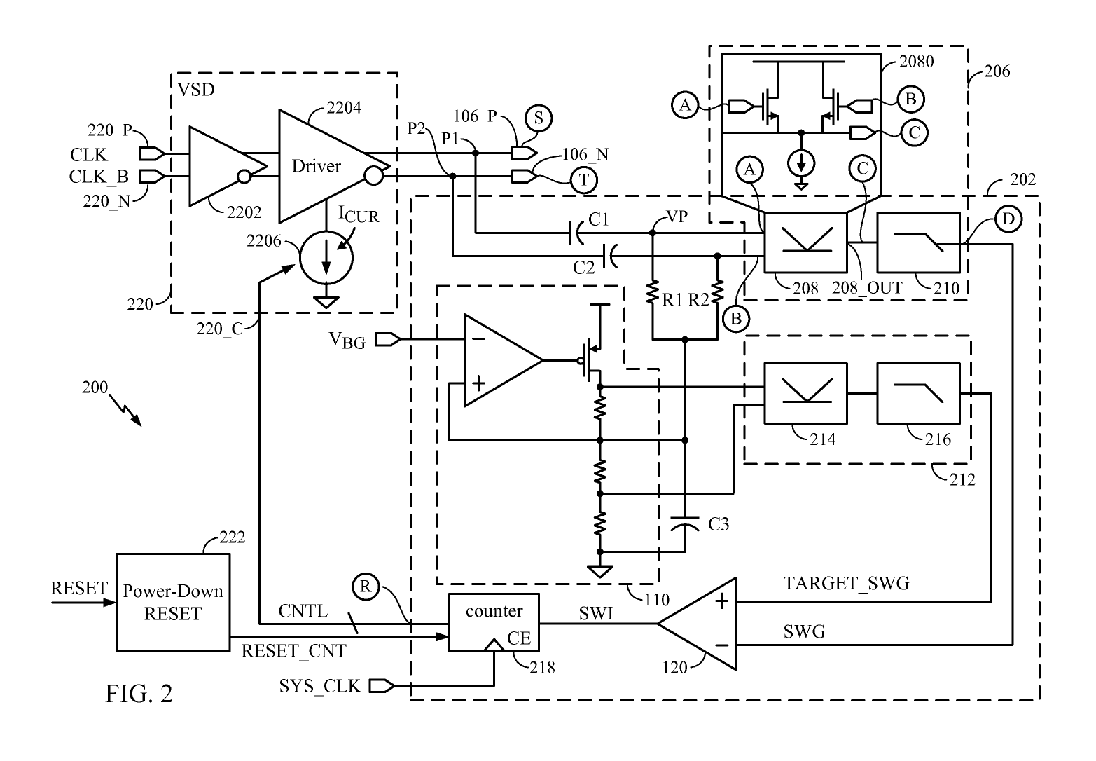

FIG. 2 shows a functional block diagram of an example ADS cable drive system 200, similar to the FIG. 1 ADS cable drive system 100, with a VSD 220 substituted for the VSD 104, and with an OSAA engine 202 representing the FIG. 1 OSAA engine 102 with example implementations for each of the swing measurement block 108, the target swing measurement block 118, and the swing increase block 122. The example VSD 220 may have a positive input 220_P and a negative input 220_N, and include a differential buffer 2202, having differential inputs (not separately labeled) coupled to the positive input 220_P and negative input 220_N, feeding a differential line buffer 2204, with a current control section 2206 receiving, at swing control input 220_C a swing control signal, such as the CNTL described in reference to FIG. 1 and controlling, in response to the CNTL value, a steering current I_{CUR}.

Referring to FIG. 2, the OSAA engine 202 uses, as implementation of the FIG. 1 swing measurement block 108, a swing measurement circuit 206 formed of a first swing measurement full wave rectifier 208, feeding a first low pass, or swing measurement smoothing filter 210. The swing measurement full wave rectifier 208 can have two inputs (shown but not separately numbered) coupled, respectively, to the VP and VN reference points described in greater detail below. The inputs to the swing measurement full wave rectifier 208 can correspond to the previously described inputs 108_P and 108_N of the FIG. 1 swing measurement block 108. The swing measurement full wave rectifier 208 can have an output 208_OUT that couples to an input (shown but not separately numbered) of a swing measurement smoothing filter 210. The swing measurement full wave rectifier 208 can be according to the simplified schematic 2080, shows one example swing measurement full wave rectifier 208, having two NMOS transistors (shown but not separately labeled) with their respective gates coupled to the inputs 208_P and 208N, feeding an output corresponding to the output 208_OUT to a steering current source (shown but not separately numbered) to ground.

With respect to the particular specifications of, and particular structure for a swing measurement full wave rectifier 208, for example according to the simplified schematic 2080, persons of ordinary skill in the art having view of the present disclosure can readily select, and/or design and construct such a circuit, applying conventional design considerations such as the frequency of the Signal_OUT, power consumption, surface area, and the like and, therefore, further detailed description is omitted.

With respect to specifications for, and particular structure for the swing measurement smoothing filter 210, considerations that may be particular to the embodiments are settling time and transients on the SWG signal, combined with the settling time and transients on the Target_SWG output from the target swing smoothing filter 216, as will be described in greater detail below. Persons of ordinary skill in the art having view of the present disclosure can readily determine the above-described settling time characteristics for a particular application, and then select, and/or design and construct a circuit implementing the target swing smoothing filter 216 using the determined characteristics, applying convention design methods and considerations and, therefore, further detailed description is omitted.

Referring still to FIG. 2, in an aspect the OSAA engine 202 uses, as one implementation of the FIG. 1 target swing measurement block 118, a target swing measurement circuit or block 212 having a second or target swing measurement full wave rectifier 214, feeding a second low pass, or target swing measurement smoothing filter 216. The target swing measurement full wave rectifier 214 can have two inputs (shown but not separately labeled) that can couple, respectively, to the NH node and the NL node of the previously described voltage ladder of the target swing generating circuit 110, to receive V_{H} and V_{L}. Regarding the function of the second or target swing measurement full wave rectifier 214, as will be appreciated by persons of ordinary skill in the art from this disclosure, if V_{H} and V_{L} were fed directly to the target swing measurement smoothing filter 216 the Target_SWG signal would be the average, namely and equal to V_{M}. Referring to the simplified schematic 2080 as an example structure for the target swing measurement full wave rectifier 214, feeding V_{H} and V_{L} to the PMOS transistor pair (shown but not separately labeled) the output of the target swing measurement full wave rectifier 214 will be a signal with an average voltage of V_{H}−V_{L}, hence Target_SWG. In one aspect the target swing measurement full wave rectifier 214 can be structured and configured identical to the swing measurement full wave rectifier 208, and the target swing measurement smoothing filter 216 can be structured and configured identical to the swing measurement smoothing filter 210. One benefit provided by this aspect is that performance variations of the swing measurement full wave rectifier 208 and swing measurement smoothing filter 210, for example due to fabrication tolerance, age and operating environment, can closely track with similar performance variations in the target swing measurement full wave rectifier 214 and target swing measurement smoothing filter 216, respectively.

Referring to FIG. 2, in one aspect the values of C1, C2, R1, R2, C3 and the values of RH, RL1 and R2, and therefore V_{H} and V_{L}, are selected so that the Target_SWG output from the target swing measurement circuit 212 will be the value that SWG output from the swing measurement circuit 206 will have when the Signal_OUT swing is at the target magnitude. Also, as previously described, in one aspect the swing comparator 120 generates, as a comparison result, the SWI at a swing increase enable value when SWG is less than Target_SWG, and generates SWG at a swing increase not enable value when SWG is not less than Target_SWG. In an aspect, the OSAA engine 202 uses a swing increase counter 218 for the swing increase block 122 of the FIG. 1 OSAA engine 102. Further to this aspect, CNTL can be the count value. The swing increase counter 218 can, in one aspect, receive SWI at a count enable port CE, and receive a system clock SYS_CLK. In another aspect the swing increase counter 218 can receive a RESET_CNT from a Power-Down/RESET block 222, described in greater detail below. The swing increase counter 218 may be an N-bit binary counter with N being any integer, for example four. Regarding the value of N, the greater the value the smaller the increments of CNTL and, hence the tighter the potential control over the swing of the Signal_OUT but, as will be understood, the longer the expected time to perform a swing adjust according to the exemplary embodiments. In an aspect the swing increase counter 218 can be configured to increment its count, (i.e., increment CNTL), at each instance of SYS_CLK when SW1 has the increase swing enable value, and to ignore SYS_CLK when SW1 has the count disable value. It will be understood that “instance” of the SYS_CLK means the clock event, e.g., rising edge, falling edge, high or low level, that causes the swing increase counter 218 to increment. Therefore, the minimum “swing increase interval” is the inverse of the frequency of the SYS_CLK. As will be described in greater detail below, the swing increase interval may be considered is specifying the settling time of the swing measurement smoothing filter 210, as well as the settling time of the target swing measurement smoothing filter 216.

Referring again to the swing measurement smoothing filter 210, it will be understood that its settling time, compared to the swing increase interval during a swing adjustment process according to at least one exemplary embodiment, may be a factor considered in its selection or design. More particularly, when a SYS_CLK instance increments the swing increase counter 218, and hence increments CNTL, the resulting increase in the swing of Signal_OUT, as measured by the swing comparator 120 comparing SWG to Target_SWG, is not known until after a swing increase loop delay. The swing increase loop delay can include the VSD 220 delay in responding to the incremented CNTL, the transient delay on the differential transmission line 106, the delay on the swing measurement full wave rectifier 208, and the delay through the swing measurement smoothing filter 210. If the settling time of the swing measurement smoothing filter 210 is overly long relative to the swing increase interval (i.e., the inverse of the SYS_CLK frequency), the SWG value and therefore the swing comparator 120 output SWI may not, at the next clock event of the SYS_CLK, accurately reflect the increase in the swing, resulting from the above-described incrementing of the swing increasing counter 218 at the preceding event of the SYS_CLK. A result may be the swing increase counter 218 being enabled for at least one increment of CNTL beyond the value at which the Signal_OUT swing met the target swing. Persons of ordinary skill in the art can readily determine whether such additional incrementing of the CNTL is tolerable in view of a particular application, and can readily select or design the swing measurement smoothing filter 210 accordingly.

Referring to FIG. 2, in one aspect a power (e.g., Vdd) remains coupled to the above-described sections of the OSAA engine 202 even after the swing comparator 120 detects SWG reaching the Target_SWG and, accordingly, changes or switches SWI from its swing increase enable value to its swing increase not enable value. In other words, in this aspect even after CNTL has been increased as previously described until the Signal_OUT swing meets the target swing the OSAA engine 202 remains in an active state.

In another aspect a Power-Down/RESET block 222 can be included, either in or associated with the OSAA engine 202, configured to receive the SWI and to switch the OSAA engine 202 to a power-down state in response to the SWI value changing from the swing increase enable value to the swing increase not enable value. Persons of ordinary skill in the art will appreciate that a wide variety of methods and means may be employed to perform power-down/RESET functions such as represented by the FIG. 2 Power-Down/RESET functional block 222. For example, power-down/RESET functions may be distributed throughout various structures implementing the various functional blocks of the OSAA engine 202. Further to this one aspect, the power-down/RESET block 222 may be configured to receive a reset signal RESET and, in response, switch the OSAA engine 202 to a power-up state. In one specific example according to this aspect, the swing increase counter 218 may be constructed using, in accordance with conventional counter design, serial flip-flops (not shown) having reset structure (not shown) in accordance with conventional flip-flop reset structure and, in such an example, the RESET signal may be connected to the input for such structure.

Referring still to FIG. 2, and continuing with description of example reset features, in an aspect the swing increasing counter 218 can be configured, for example in association with the Power-Down/RESET block 222, to remain disabled during the power-down state and, upon receiving the RESET_CNT from the power-down/RESET block, to reset or zero CNTL to a given start or default value. Assuming the Power-Down/RESET block 222 switches the remaining hardware (not explicitly shown in FIG. 2) of the OSAA engine 202 to a power up or active state, the zeroing or other resetting of the swing increase counter 218 can cause CNTL to reduce the swing of the VSD 220, causing SWG to fall below the Target_SWG. The swing comparator 120, in response, generates SWI at the swing increase enable value and, at the next instance of SYS_CLK, the swing increase counter 218 increments CNTL. This process will continue until SWG first reaches the Target_SWG level, as previously described, whereupon SWI switches back to the swing increase not enable value, causing the Power-Down/RESET block 222 to power down the OSAA engine 202.

Referring to FIG. 1 the example ADS cable drive system 100 is shown as using the example OSAA engine 102 to control only one adjustable swing line driver, namely the VSD 104. The FIG. 2 example ADS cable drive system 200 likewise is shown as using the example OSAA engine 202 to control only adjustable swing line driver, VSD 220. According to at least one embodiment, a single OSAA engine such as the previously described OSAA engine 102 or OSAA engine 202, can be particularly arranged to control the output swing of a plurality of adjustable swing line drivers, each driving a corresponding one of a plurality of lines of, for example, a parallel multi-line line cable, such as an HDMI cable. As will be appreciated by persons of ordinary skill in the art from this disclosure, since the plurality of transmission lines of a parallel multi-line line cable, such as an HDMI cable, are in the same cable, all will have approximately the same length and, according to conventional parallel line receiver design, all will terminate at approximately the same load impedance. Moreover, as described in greater detail below, according to at least one exemplary embodiment each of the plurality of line drivers is provided with an internal selectable output impedance. As previously described, the selected value of the output impedance can, absent the CNTL generated by the swing increase counter 218, be a significant determinant of the swing of the Signal_OUT. Further, as will be understood from the described example arrangements and operations, one general operation selects all the internal selectable output impedances in a group manner. It will be appreciated from this disclosure that at least one exemplary embodiment provides a multi-line automatic swing adjust cable drive system that can exploit this similarity in impedance among multiple individually driven lines of a cable.

According to a least one exemplary embodiment, the differential transmission line 106 shown in the FIG. 1 ADS cable drive system 100 can be assumed to be one of a plurality of differential transmission lines within a cable such as an HDMI cable. In an aspect, the OSAA engine 102 can adjust (e.g., increase) the swing control signal CNTL, as previously described, until the SWG output from the swing measurement block 108 matches the Target_SWG output by the target swing measurement block 118. However, further to this exemplary embodiment the generated CNTL controls not only the swing of the depicted VSD 104, but also the swing on each of a plurality of other adjustable swing line drivers (not shown on FIG. 1), each driving a corresponding one of the remaining plurality of differential transmission lines. Likewise, referring to FIG. 2, in at least one exemplary embodiment, the differential transmission line 106 to which the OSAA engine 202 is coupled can be used by the OSAA engine 202 to adjust (e.g., increase) the swing control signal CNTL until the SWG output from the swing measurement circuit 206 matches the Target_SWG output by the target swing measurement circuit 212, with CNTL controlling not only the swing of the depicted VSD 220, but also the swing on each of a plurality of adjustable swing line drivers (not shown on FIG. 2), each driving a corresponding one of the remaining plurality of differential transmission lines.

In one aspect, a multi-line automatic swing adjust cable drive system according to at least one exemplary embodiment can couple an automatic swing adjust engine to a particular one transmission line of a plurality of transmission lines within a multi-line cable, with the particular one transmission line carrying a signal having a frequency substantially lower than the frequency of signals carried by other of the plurality of transmission lines. Further to the at least one exemplary embodiment, in an aspect the swing control signal generated by the automatic swing adjust engine can control all of the adjustable swing line drivers, including the adjustable swing line driver driving the particular one transmission line carrying the lower frequency signal and each of the adjustable swing line drivers driving a higher frequency signal on a corresponding one of the remaining transmission lines. One example, described in greater detail below, provides a multi-line automatic swing adjust cable driver system according to at least one exemplary embodiment, having an automatic swing adjust engine coupled to a clock transmission line of an HDMI cable, carrying a clock signal having approximately 1/10 of the frequency of signals carried by other transmission lines of the HDMI cable. In the one example, the automatic swing adjust engine coupled to the clock line outputs a swing control signal that is distributed to, and that controls the swing of all of the adjustable swing line drivers, corresponding to the clock transmission line and corresponding to the transmission lines carrying the higher (10 times) frequency signals. Among the benefits provided by multi-line automatic swing adjust cable driver systems according to this at least one exemplary embodiment is an automatic swing adjust engine having reduced design complexity and relaxed parameter value tolerance as compared to an automatic swing adjust engine coupled to, and measuring the output swing one, one of the transmission lines carrying a higher frequency signal.

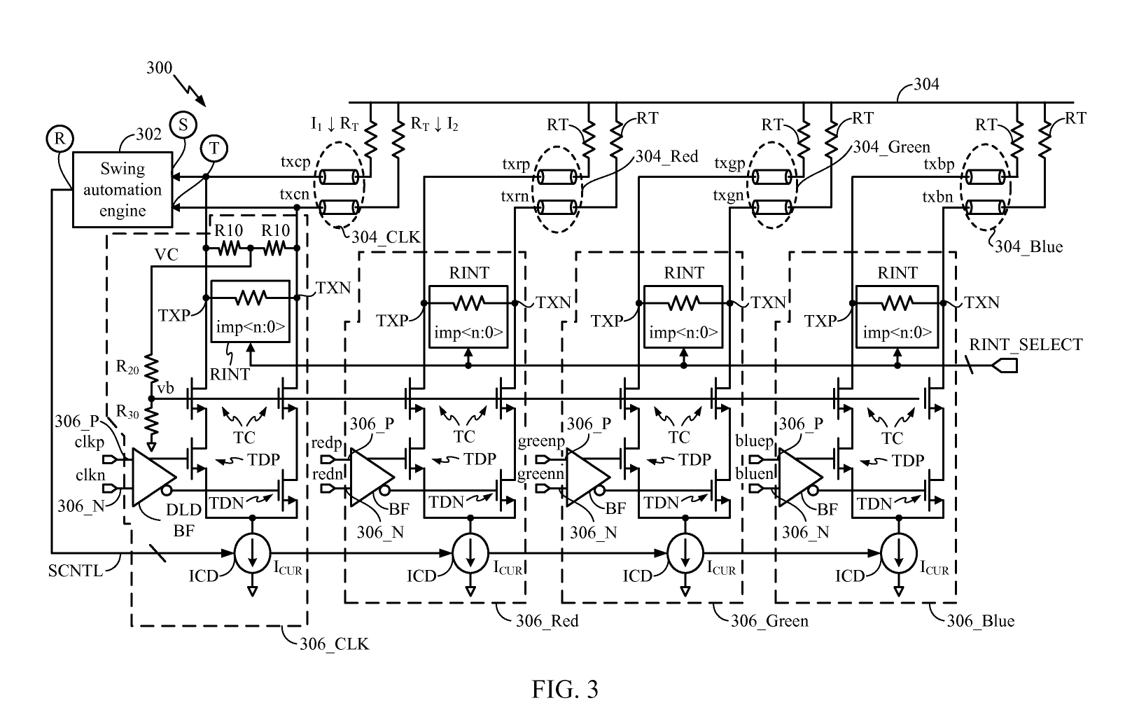

FIG. 3 shows a simplified schematic diagram of one automatic multi-line cable swing adjustment system 300 according to one exemplary embodiment, having an automatic swing adjust engine 302 (alternatively referenced as “swing automation engine 302”) coupled to a clock transmission line 304_CLK of an HDMI cable 304, and generating a common swing adjust signal SCNTL, with the HDMIO cable also having a “red” transmission line, 304_Red, a “green” transmission line 304_Green, and a “blue transmission line, 304_Blue. For brevity, the phrase “automatic multi-line cable” will be referenced in the alternative as “AMLC.” It will be understood that “AMLC” is only an arbitrary name for referencing described examples, having no inherent meaning. It will also be understood that the transmission cable implemented by the HDMI cable 304 is not intended as a limitation on the scope of any embodiment, or any aspect of any embodiment and, instead, HDMI cable 304 is only one example multi-line transmission cable on which embodiments such as the FIG. 3 example AMLC swing adjustment system 300 can be practiced.

Referring still to FIG. 3, the automatic swing adjust engine 302 may be implemented by, for example, a circuit according to the FIG. 1 simplified schematic of the OSAA engine 102 or a circuit according to the FIG. 2 simplified schematic of the OSAA engine 202. For purposes of focusing on novel aspects without introducing unnecessary details that are not particular to the same, example aspects and operations of the FIG. 3 AMLC swing adjustment system 300 will be described assuming, as an example, the automatic swing adjust engine 302 being implemented by the FIG. 2 OSAA engine 202. Further to this example, FIGS. 2 and 3 show common reference points “R,” “S,” and “T.”

Referring to FIG. 3, the SCNTL generated by the automatic swing adjust engine 302 can be distributed to an adjustable swing line driver 306_CLK driving the clock transmission line 304 CLK, an adjustable swing line driver 306_Red driving the red transmission line 304_Red, an adjustable swing line driver 306_Green driving the green transmission line 304_Green, and an adjustable swing line driver 306_Blue driving the blue transmission line 304_Blue. For brevity, the term “adjustable swing line drivers 306” will be used as a collective reference to the adjustable swing line driver 306_CLK, the adjustable swing line driver 306_Red, the adjustable swing line driver 306_Green, and the adjustable swing line driver 306_Blue. Each of the adjustable swing line drivers 306 has inputs 306_P and 306_N feeding a differential buffer BX, respectively receiving a differential clock signal “clkp” and “clkn,” a differential red signal “redp” and “redn,” a differential green signal “greenp” and “greenn,” and a differential blue signal “bluep” and “bluen.” As previously described, the differential clock signal clkp/clkn can have a frequency approximately 1/10 of the frequency of the redp/redn, greenp/greenn and bluep/bluen signals.

Continuing to refer to FIG. 3, each of the adjustable swing line drivers 306 includes an internal adjustable output impedance R_{INT}, coupled between its output terminal lines TXP and TXN, controlled by an impedance select control line RINT_SELECT. The adjustable swing line driver 306_CLK also includes a bandgap reference voltage generating circuit (shown but not separately labeled) formed of, for example, a series arrangement of two resistors R₁₀ coupled between its output terminal lines TXP and TXN, parallel to its adjustable output impedance R_{INT}, and a path from a midpoint at the coupling between the two resistors R₁₀ to ground, the path including a series arrangement of resistors R₂₀ and R₃₀. A node at the coupling of R₂₀ and R₃₀ generates a bandgap reference voltage V_{BG}. The bandgap reference voltage V_{BG} is coupled to the gate (shown but not separately labeled) of a mirrored pair of clamp transistors TC within each of the adjustable swing line drivers 306. Each of the adjustable swing line drivers 306 also includes a mirrored pair of drive transistors TDP and TDN, with gates driven by positive and negative differential outputs, respectively, (shown but not separately labeled) of a differential buffer BX. For each adjustable swing line driver 306, the drive transistor TDP controls the drive current of the output terminal TXP and the drive transistor TDN controls the drive current of the output terminal TXN. The adjustable swing of each of the adjustable swing line drivers 306 is provided by an adjustable steering current device ICD that controls a steering current I_{CUR} in accordance with the common swing control line SCNTL.

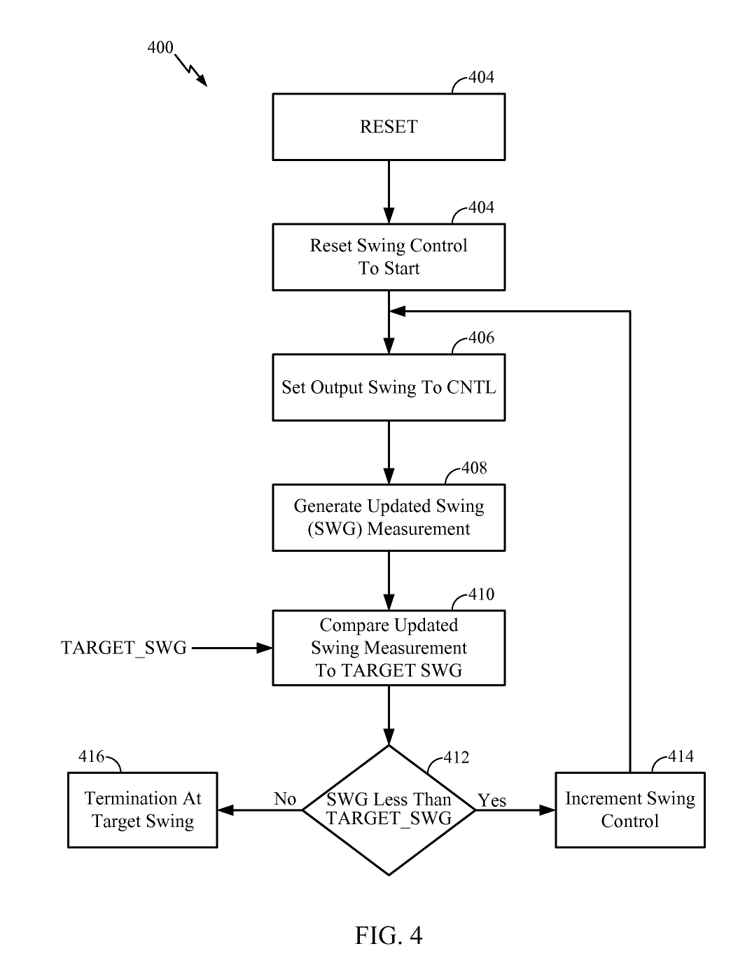

FIG. 4 shows a functional block flow diagram of one example reset and swing adjust process 400 according to at least one exemplary embodiment. To assist in understanding concepts, example operations of the reset and swing adjust process 400 may be referenced to the FIG. 2 ADS cable drive system 200. Further, operations of the reset and swing adjust process will be described in terms of a system clock, such as the SYS_CLK counter clock for the swing increase counter 218 of the FIG. 2 example ADS cable drive system 200. It will be understood, however, that the reset and swing adjust process 400 is not limited to a clocked or discrete time hardware, and that the FIG. 2 ADS cable drive system 200 is only one example system for practicing the reset and swing adjust process 400, and other processes according to at least one exemplary embodiment, and is not intended as limiting the scope of any of the exemplary embodiments or any aspect thereof.

Referring to FIG. 4, one example of the reset and swing adjust process 400 can start at a reset 402. The reset 402 may, for example, be the FIG. 2 RESET signal feeding the Power-Down/RESET block 222. An example reset and swing adjust process 400 may then go to 404 and reset the line driver swing control signal, e.g., the CNTL signal of FIGS. 1 and 2. Referring to FIG. 2, the RESET_CNT signal output by the Power-Down/RESET block 222 can be an example of the FIG. 4 resetting at 404 of the line driver swing control. It will be assumed that the start level of the line driver swing control signal (e.g., CNTL of FIGS. 1 and 2) established at 404 is set, for example in the design of the hardware performing the reset and swing adjust process 400, to be lower than the estimated final value of the swing control signal at the lowest output impedance to which the switchable output impedance (e.g., lowest value of the FIG. 3 R_{INT}) of the adjustable swing line driver can be switched.

Continuing with the above description of an example operation of the reset and adjust process 400, after the resetting of the line driver swing control signal at 404 the process may go to 406 to set the swing of the line driver in accordance with the swing control signal which, in this instance, is the start level set at 404, then to 408 to generate an updated output swing measurement and then to 410 to compare the updated output swing measurement to a reference swing measurement. One example of a setting at 406 of the swing of line driver is the FIG. 2 current control section 2206 changing in response to receiving the reset CNTL value. An example of the generating at 408 of an updated swing measurement is the FIG. 1 swing measurement block 108, or the FIG. 2 swing measurement circuit 206 generating an updated SWG. One example comparing at 410 of the updated swing measurement to the target swing measurement is the FIG. 1 and FIG. 2 example comparing by the swing comparator of SWG to Target_SWG.

Continuing with description of example operations according to the reset and swing adjustment process 400, after the comparing at 410 of the updated swing measurement to the target swing measurement, the reset and swing adjustment process 400 can go to the swing increase decision block 412. The swing increase decision block 412 is “YES” if the comparison at 410 indicates the output swing is less than the target swing, whereupon the process goes to 414, increments or otherwise increases the line driver swing control signal (e.g., the CNTL of FIGS. 1 and 2) then to 406 to adjust the driver swing and then to 408 to again generate an updated swing measurement and continue as previously described. Referring to FIG. 2 and FIG. 3, an example of performing both the FIG. 4 swing increase decision block 412 and swing increase at 414 is the SWI being at a count enable state when an instance of the SYS_CLK is received by the increase swing counter 218.

Continuing with description of example operations according to the reset and swing adjustment process 400, the instant example began with a reset signal at 402, in turn causing a reset of the line driver swing control and, therefore, the swing increase decision block 412 will be YES. In one example, a loop of 414 to 408 to 410 to 412 and then to 414 and repeating the loop around the FIG. 4 block flow of the reset and swing adjustment process 400 will continue until the first instance where the comparison at 410 indicates the updated swing measurement is not less than the target swing measurement. The result will be a “NO” at the swing increase decision block 412, sending the operation to the termination at target swing block 416. According to one exemplary embodiment the termination at target swing block 416 may include latching (not shown in FIG. 4) the line driver swing control signal, either at its generator or at the one or more adjustable line drivers controlled by that line driver swing control signal. Referring to the FIG. 2 example ADS cable drive system 200, one example of this latching aspect can be a latch feature of the swing increase counter 218. Another example of this latching aspect can be a latch (not shown in FIG. 2) within the adjustable swing line driver VSD 220. According one exemplary embodiment the termination at target swing block 416 may include switching off (not shown in FIG. 4) a power supply to certain components, portions or sections of the particular hardware performing the reset and swing adjustment process 400.

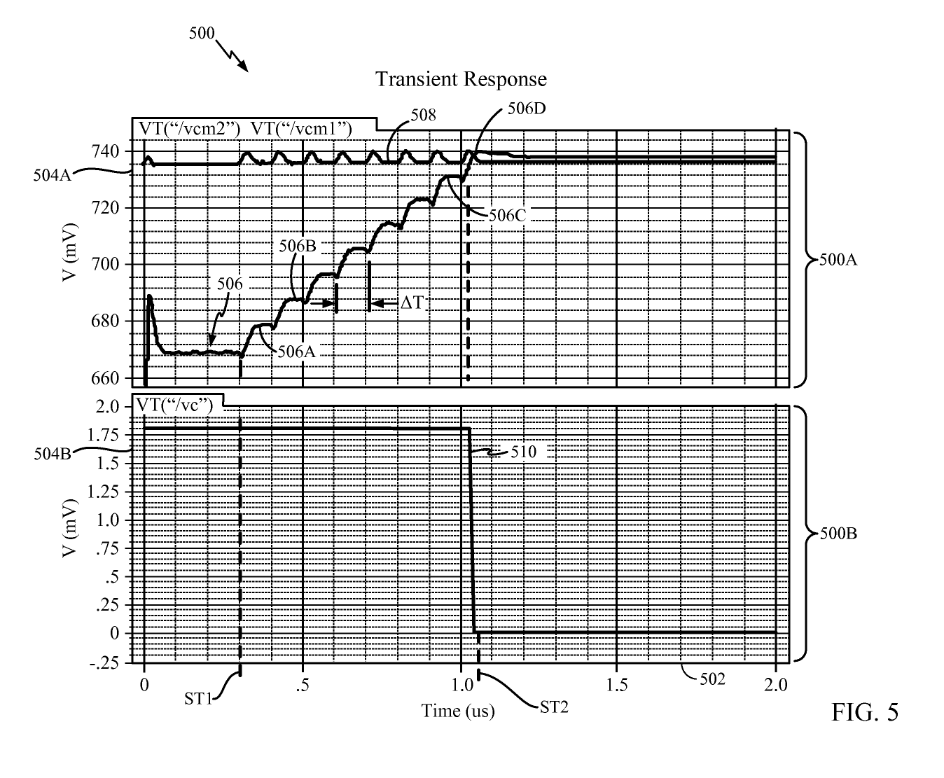

FIG. 5 shows a computer simulation result 500, showing on signal graphs 500A and 500B certain characteristics of one example line driver automatic swing adjustment according to one exemplary embodiment. The computer simulation that produced the computer simulation result 500 was based on a cable drive system according to the FIG. 3 schematic, using computer model of the FIG. 2 OSAA engine 202 for the FIG. 3 swing automation engine 302, and using the following simulation parameters: R_{INT} at 200 Ohms local power domain (Vdd powering the FIG. 3 adjustable swing line drivers 306) of 1.7 volts, receive power domain 3.3 volts, FIG. 2 resistor R1, R2 values approximately 24,000 Ohms Referring to FIG. 5, time axis 502 is a 2 microsecond span common to the signal graphs 500A and 500B, which are separated to allow different scales of amplitude, for graphical clarity. Signal graph 500A has a vertical axis 504A ranging from approximately 660 millivolts to 740 millivolts, and signal graph 500B has a vertical axis 504B ranging from a low of −0.25 volts to +1.75 volts.

Referring to signal graph 500A, plot line 506 is the simulated signal swing measurement SWG output from the computer model of the FIG. 2 swing measurement smoothing filter 210, and plot line 508 is the simulated Target_SWG signal output from the computer model of the target swing measurement smoothing filter 216. The time span from 0 to ST1 (at 0.3 microseconds) reflects a simulated reset operation, such as the CNTL output of the FIG. 2 swing increase counter 218 being reset to a starting value, and time instant ST1 represents a first instance of the simulated SYS_CLK at the swing increase counter 218 after that simulated reset. As previously described, in an aspect the starting value of CNTL produces a swing smaller than the target swing, and the signal graph 500A shows this as the difference up until ST1, between plot line 508 and plot line 506, being the largest throughout the simulated span. At ST1 plot line section 506A of the simulated swing measurement SWG reflects a one increment increase in the CNTL output of the computer model of the swing increase counter 218, raising SWG and closing the difference between the simulated SWG at that point and the simulated Target_SWG on the plot line 508. The next plot line section, 506B of the simulated swing measurement SWG reflects another one increment increase in the CNTL output of the computer model of the swing increase counter 218, raising SWG and further closing the difference between the simulated SWG at that point and the simulated Target_SWG on the plot line 508. The simulation results on the signal graph 500A show the process continuing until the increment causing the SWG at 506C to increase to the value at 506D that is no longer less than the simulated Target_SWG plot line 508. The interval ΔT represents the previously described swing increase interval, which can be the inverse of the SYS_CLK frequency.

Referring to signal graph 500B, plot line 510 is the simulated output SWI of the computer model of the swing comparator 120, showing at ST2 the SWI changing from a swing increase enable value of approximately 1.75 volts to a swing increase not enable value of approximately 0 volts.

As can be appreciated from the example embodiments, and example aspects and operations of the same that are described above, and that are further depicted by the attached figures, benefits provided by automatic adjustable swing engines and by automatic adjustable swing cable driver systems and methods of the exemplary embodiments include, but are not limited to, automatic adjustment of cable driver swing to accommodate various different impedances.

One addition benefit, provided by embodiments combining an automatic adjustable swing engine with a user-selectable output impedance that can be internal to the adjustable swing line drivers, is a full utilization of the user-selectable output impedance without loss of signal integrity due to varying swing, and without requiring a manual swing adjustment. A related benefit provided by embodiments combining an automatic adjustable swing engine with a user-selectable output impedance that can be internal to the adjustable swing line drivers, is an end user flexibility in optimizing the driver impedance for particular applications, while at the same time ensuring the swing remains within specifications

Still another benefit that can be provided by automatic swing adjustment engines according to an aspect of various exemplary embodiments is a process by which a user switches among different output impedances of the adjustable swing line drivers, looking for an optimal selection that minimizes reflections, knowing that after each switching to try another impedance, an automatic swing adjustment keeps the swing within specifications. Still another benefit, among others, provided by the aspect is a can be a significantly higher likelihood of a user finding an optimum impedance, i.e., the impedance that provides minimum impedance mismatch and, therefore, maximum reduction of unwanted signal reflections.

In view of exemplary systems shown and described above, methodologies that may be implemented in accordance with the disclosed subject matter, will be better appreciated with reference to various flow charts. While, for purposes of simplicity of explanation, methodologies are shown and described as a series of blocks, it is to be understood and appreciated that the claimed subject matter is not limited by the number or order of blocks, as some blocks may occur in different orders and/or at substantially the same time with other blocks from what is depicted and described herein. Moreover, not all illustrated blocks may be required to implement methodologies described herein. It is to be appreciated that functionality associated with blocks may be implemented by software, hardware, a combination thereof or any other suitable means (e.g. device, system, process, or component). Additionally, it should be further appreciated that methodologies disclosed throughout this specification are capable of being stored on an article of manufacture to facilitate transporting and transferring such methodologies to various devices. Those skilled in the art will understand and appreciate that a methodology could alternatively be represented as a series of interrelated states or events, such as in a state diagram. Further, the various methods disclosed herein can include employing a processor executing computer executable instructions stored on a computer readable storage medium to implement the methods.

It will be appreciated that data store (e.g., memories) components described herein may include or may be implemented using volatile memory, nonvolatile memory, or both. Nonvolatile memory may include or may be implemented with any non-volatile memory technology capable of meeting performance requirements pertaining to the particular memory function implemented, which can be readily ascertained by persons of ordinary skill in the art upon reading this disclosure, and may include, as illustrative but limitative examples, read only memory (ROM), programmable ROM (PROM), electrically programmable ROM (EPROM), electrically erasable ROM (EEPROM), or flash memory. Volatile memory may include or may be implemented with any volatile memory technology capable of meeting performance requirements pertaining to the particular memory function implemented, which can be readily ascertained by persons of ordinary skill in the art upon reading this disclosure, and may include, as illustrative but limitative examples, synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), and direct Rambus RAM (DRRAM). Memory of the various aspects is intended to comprise, without being limited to, these and any other suitable types of memory.

It is to be understood that aspects described herein may be implemented by hardware, software, firmware or any combination thereof When implemented in software, functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if software is transmitted from a website, server, or other remote source using a coaxial cable, fiber optic cable, twisted pair, digital subscriber line (DSL), or wireless technologies such as infrared, radio, and microwave, then coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

Various illustrative logics, logical blocks, modules, and circuits described in connection with aspects disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform functions described herein. A general-purpose processor may be a microprocessor, but, in the alternative, processor may be any conventional processor, controller, microcontroller, or state machine. A processor may also be implemented as a combination of computing devices, for example, a combination of a DSP and a microprocessor, a plurality of microprocessors, one or more microprocessors in conjunction with a DSP core, or any other such configuration. Additionally, at least one processor may comprise one or more modules operable to perform one or more of the steps and/or actions described herein.

For a software implementation, techniques described herein may be implemented with modules (e.g., procedures, functions, and so on) that perform functions described herein. Software codes may be stored in memory units and executed by processors. Memory unit may be implemented within processor or external to processor, in which case memory unit can be communicatively coupled to processor through various means as is known in the art. Further, at least one processor may include one or more modules operable to perform functions described herein.

Various aspects or features described herein may be implemented as a method, apparatus, or article of manufacture using standard programming and/or engineering techniques. The term “article of manufacture” as used herein is intended to encompass a computer program accessible from any computer-readable device, carrier, or media. For example, computer-readable media can include but are not limited to magnetic storage devices (e.g., hard disk, floppy disk, magnetic strips, etc.), optical disks (e.g., compact disk (CD), digital versatile disk (DVD), etc.), smart cards, and flash memory devices (e.g., EPROM, card, stick, key drive, etc.). Additionally, various storage media described herein can represent one or more devices and/or other machine-readable media for storing information. The term “machine-readable medium” can include, without being limited to, wireless channels and various other media capable of storing, containing, and/or carrying instruction(s) and/or data. Additionally, a computer program product may include a computer readable medium having one or more instructions or codes operable to cause a computer to perform functions described herein.

Further, the steps and/or actions of a method or algorithm described in connection with aspects disclosed herein may be embodied directly in hardware, in a software module executed by a processor, or a combination thereof A software module may reside in RAM memory, flash memory, ROM memory, EPROM memory, EEPROM memory, registers, a hard disk, a removable disk, a CD-ROM, or any other form of storage medium known in the art. An exemplary storage medium may be coupled to processor, such that processor can read information from, and write information to, storage medium. In the alternative, storage medium may be integral to processor. Further, in some aspects, processor and storage medium may reside in an ASIC. Additionally, ASIC may reside in a user terminal In the alternative, processor and storage medium may reside as discrete components in a user terminal Additionally, in some aspects, the steps and/or actions of a method or algorithm may reside as one or any combination or set of codes and/or instructions on a machine readable medium and/or computer readable medium, which may be incorporated into a computer program product.

While the foregoing disclosure discusses illustrative aspects and/or embodiments, it should be noted that various changes and modifications could be made herein without departing from the scope of described aspects and/or embodiments as defined by the appended claims. Accordingly, described aspects are intended to embrace all such alterations, modifications and variations that fall within scope of appended claims. Furthermore, although elements of described aspects and/or embodiments may be described or claimed in the singular, the plural is contemplated unless limitation to the singular is explicitly stated. Additionally, all or a portion of any aspect and/or embodiment may be utilized with all or a portion of any other aspect and/or embodiment, unless stated otherwise.

What is claimed is:

1. A method for adjusting an output swing of a driver, comprising:
generating a target swing measurement signal;
generating a swing measurement signal based on a magnitude of the output swing; and
controlling the output swing based on the swing measurement signal and the target swing measurement signal.

2. The method of claim 1, wherein generating the swing measurement signal comprises:
extracting an AC component of the output swing; and
generating the swing measurement signal based on the extracted AC component.

3. The method of claim 2, wherein generating the swing measurement signal based on the extracted AC component comprises:
rectifying the AC component to generate a DC swing measurement signal; and
generating the swing measurement signal based on the DC measurement signal.

4. The method of claim 1 wherein controlling the output swing includes comparing the swing measurement signal to the target swing measurement signal and adjusting the output swing based, at least in part, on the comparing.

5. The method of claim 4, wherein adjusting the output swing based, at least in part, on the comparing includes:
incrementing a counter output count in response to the comparing indicating the swing measurement signal to be lower than the target swing measurement signal; and
increasing the output swing based on the counter output count.

6. The method of claim 5, further comprising repeating the comparing the swing measurement signal to the target swing measurement signal and adjusting the output swing based, at least in part, on the comparing until the comparing indicates the swing measurement signal to be not lower than the target swing measurement signal.

7. The method of claim 1, further comprising:
resetting a swing control signal to a start value;
controlling the output swing based on the swing control signal;
generating an updated swing measurement signal based on the magnitude of the output swing;
increasing the swing control signal; and
repeating the controlling the output swing, generating the updated swing measurement signal and increasing the swing control signal until the updated swing measurement signal is not less than a given target swing measurement.

8. The method of claim 7, wherein the swing control signal is a counter output count,
wherein resetting the swing control signal comprises resetting the counter output count, and
wherein increasing the swing control signal comprises incrementing the counter output count.

9. The method of claim 1, wherein generating the target swing measurement signal includes:
generating a high swing voltage and a low swing voltage based on a reference voltage; and
generating the target swing measurement signal based, at least in part, on the high swing voltage and the low swing voltage.

10. The method of claim 9, wherein generating the target swing measurement signal further includes generating a common mode reference voltage, midpoint between the high swing voltage and the low swing voltage, and wherein the AC component is extracted as a swing relative to the common mode reference voltage.

11. The method of claim 1, wherein the driver includes a selectable output impedance selectable from a plurality of impedances, and the method further comprises:
selecting an output impedance from the plurality of impedances;
resetting a swing control signal to a start value;
controlling the output swing based on the swing control signal; generating an updated swing measurement signal based on the magnitude of the output swing;
increasing the swing control signal; and
repeating the controlling the output swing, generating the updated swing measurement signal and increasing the swing control signal until the updated swing measurement signal is not less than a given target swing measurement.

12. The method of claim 11, further comprising controlling the output swing of a plurality of line drivers based on the swing control signal.

13. A driver swing adjustment apparatus for a driver having a signal input, a signal output, and a swing control input, comprising:
a swing measurement circuit coupled to the signal output, for generating a swing measurement signal according to a swing on the signal output;
a target swing measurement circuit for generating a target swing measurement signal according to a target swing reference voltage; and
a feedback signal generator for providing a control signal to the swing control input, based on the swing measurement signal and the target swing measurement signal.

14. The driver swing adjustment apparatus of claim 13, wherein the feedback signal generator comprises:
a comparator that compares the swing measurement signal to the target swing measurement signal and generates a corresponding comparison result; and
a swing increase circuit that generates the control signal based on the comparison result.

15. The driver swing adjustment apparatus of claim 14, wherein the swing increase circuit includes a counter to receive a system clock and to increment a counter output based on the system clock and the comparison result, and that outputs the control signal based on the counter output.

16. The driver swing adjustment apparatus of claim 15, wherein the counter has a reset input and resets the counter output in response to given reset signal on the reset input.

17. The driver swing adjustment apparatus of claim 15, wherein the comparator generates the comparison result as a swing increase enable signal when the swing measurement signal is less than the target swing measurement signal, and as a swing increase not enable signal when the swing measurement signal is not less than the target swing measurement signal, and wherein the counter increments the counter output in response to the swing increase enable signal and the system clock.

18. The driver swing adjustment apparatus of claim 15, wherein the counter has a reset input and resets the counter output in response to given reset signal on the reset input.

19. The driver swing adjustment apparatus of claim 13, further comprising a target swing reference voltage generator that, based on a given reference voltage, generates the target swing reference voltage,
wherein the target swing measurement circuit is AC coupled to the target swing reference voltage,
wherein the target swing reference voltage generator generates a reference midpoint voltage, generates a low swing reference voltage and a generates a high swing reference voltage relative to the reference midpoint voltage, and generates the target swing reference voltage based on the low swing reference voltage and the high swing reference voltage, and
wherein the target swing measurement circuit extracts an AC component of the target swing reference voltage, and generates the target swing measurement signal based on the AC component relative to the reference midpoint voltage.

20. The driver swing adjustment apparatus of claim 19, wherein the swing measurement circuit comprises a first full wave rectifier that rectifies the AC component to generate an unfiltered swing measurement signal and a first low pass smoothing filter that smoothes the unfiltered swing measurement signal and outputs the swing measurement signal as a corresponding DC swing signal.

21. The driver swing adjustment apparatus of claim 20, wherein the target swing measurement circuit comprises a second full wave rectifier that rectifies the high swing reference voltage and the low swing reference voltage to generate an unfiltered target swing measurement signal and a second low pass smoothing filter that smoothes the unfiltered target swing measurement signal and outputs the target swing measurement signal as a corresponding DC target swing signal.

22. An adjustable swing cable driver apparatus for a driver having a signal input, differential signal outputs, and a swing control input, comprising:
a selectable output impedance matching bridge coupling the differential signal outputs;
a swing measurement circuit coupled to the differential signal outputs, for generating a swing measurement signal according to a swing on the signal output;
a target swing signal generator for generating a target swing measurement signal according to a target reference swing; and
a feedback signal generator for providing a control signal to the swing control input, based on the swing measurement signal and the target swing measurement signal.

23. A method for adjusting an output swing of a driver, comprising:
step of generating a target swing measurement signal;
step of generating a swing measurement signal based on a magnitude of the output swing; and
step controlling the output swing based on the swing measurement signal and the target swing measurement signal.

24. The method of claim 23, wherein generating the swing measurement signal comprises:
extracting an AC component of the output swing; and
generating the swing measurement signal based on the extracted AC component.

25. The method of claim 24, wherein generating the swing measurement signal based on the extracted AC component comprises:
rectifying the AC component to generate a DC swing measurement signal; and
generating the swing measurement signal based on the DC swing measurement signal.

26. The method of claim 23, wherein controlling the output swing includes comparing the swing measurement signal to the target swing measurement signal and adjusting the output swing based, at least in part, on the comparing.

27. The method of claim 26, wherein adjusting the output swing based, at least in part, on the comparing includes:
incrementing a counter output count in response to the comparing indicating the swing measurement signal to be lower than the target swing measurement signal; and
increasing the output swing based on the counter output count.

28. The method of claim 27, further comprising step repeating the step of comparing the swing measurement signal to the target swing measurement signal and the step of adjusting the output swing based, at least in part, on the step of comparing, until the comparing indicates the swing measurement signal to be not lower than the target swing measurement signal.

29. The method of claim 23, further comprising:
step of resetting a swing control signal to a start value;
step of controlling the output swing based on the swing control signal;
step of generating an updated swing measurement signal based on the magnitude of the output swing;
step of increasing the swing control signal; and
step of repeating the controlling the output swing, generating the updated swing measurement signal and increasing the swing control signal until the updated swing measurement is not less than a given target swing measurement.

30. The method of claim 29, wherein the swing control signal is a counter output count,
wherein resetting the swing control signal comprises resetting the counter output count, and
wherein increasing the swing control signal comprises incrementing the counter output count.

31. The method of claim 23, wherein generating the target swing measurement signal includes:
generating a high swing voltage and a low swing voltage based on a reference voltage; and
generating the target swing measurement signal based, at least in part, on the high swing voltage and the low swing voltage.

32. The method of claim 31, wherein generating the target swing measurement signal further includes generating a common mode reference voltage, midpoint between the high swing voltage and the low swing voltage, and wherein the AC component is extracted as a swing relative to the common mode reference voltage.

33. The method of claim 23, wherein the driver includes a selectable output impedance selectable from a plurality of impedances, and the method further comprises:
step of selecting an output impedance from the plurality of impedances;
step of resetting a swing control signal to a start value;
step of controlling the output swing based on the swing control signal;
step of generating an updated swing measurement signal based on the magnitude of the output swing;
step of increasing the swing control signal; and
repeating, in order, the step of controlling the output swing, the step of generating the updated swing measurement signal and the step of increasing the swing control signal until the updated swing measurement is not less than a given target swing measurement.

34. The method of claim 33, further comprising step of controlling the output swing of a plurality of line drivers based on the swing control signal.

35. An apparatus for adjusting an output swing of a driver, comprising:
means for generating a target swing measurement signal;
means for generating a swing measurement signal based on a magnitude of the output swing; and
means for controlling the output swing based on the swing measurement signal and the target swing measurement signal.

36. The apparatus of claim 35, wherein generating the swing measurement signal comprises:
extracting an AC component of the output swing; and
generating the swing measurement signal based on the extracted AC component.

37. The apparatus of claim 36, wherein generating the swing measurement signal based on the extracted AC component comprises:
rectifying the AC component to generate a DC swing measurement signal, and
generating the swing measurement signal based on the DC swing measurement signal.

38. The apparatus of claim 35, wherein controlling the output swing includes comparing the swing measurement signal to the target swing measurement signal and adjusting the output swing based, at least in part, on the comparing.

39. The apparatus of claim 38, wherein adjusting the output swing based, at least in part, on the comparing includes:
incrementing a counter output count in response to the comparing indicating the swing measurement signal to be lower than the target swing measurement signal; and
increasing the output swing based on the counter output count.

40. The apparatus of claim 39, further comprising means for repeating the comparing the swing measurement signal to the target swing measurement signal and adjusting the output swing based, at least in part, on the comparing until the comparing indicates the swing measurement signal to be not lower than the target swing measurement signal.

41. The apparatus of claim 35, further comprising:
means for resetting a swing control signal to a start value;
means for controlling the output swing based on the swing control signal;
means for generating an updated swing measurement signal based on the magnitude of the output swing;
means for increasing the swing control signal; and
means for repeating the controlling the output swing, generating the updated swing measurement signal and increasing the swing control signal until the updated swing measurement is not less than a given target swing measurement.

42. The apparatus of claim 41, wherein the swing control signal is a count,
wherein resetting the swing control signal comprises resetting the count, and
wherein increasing the swing control signal comprises incrementing the count.

43. The apparatus of claim 35, wherein generating the target swing measurement signal includes:
generating a high swing voltage and a low swing voltage based on a reference voltage; and
generating the target swing measurement signal based, at least in part, on the high swing voltage and the low swing voltage.

44. The apparatus of claim 43, wherein generating the target swing signal further includes generating a common mode reference voltage, midpoint between the high swing voltage and the low swing voltage, and wherein the AC component is extracted as a swing relative to the common mode reference voltage.

45. The apparatus of claim 35, wherein the driver includes a selectable output impedance selectable from a plurality of impedances, and the apparatus further comprises:
means for selecting an output impedance from the plurality of impedances;
means for resetting a swing control signal to a start value;
means for controlling the output swing based on the swing control signal;
means for generating an updated swing measurement signal based on the magnitude of the output swing;
means for increasing the swing control signal; and
means for repeating the controlling the output swing, generating the updated swing measurement signal and increasing the swing control signal until the updated swing measurement is not less than a given target swing measurement.

46. The apparatus of claim 45, further comprising means for controlling the output swing of a plurality of line drivers based on the swing control signal.
